(19) United States
(12) Patent Application Publication
(10) Pub. No.: US 2012/0062507 A1
(43) Pub. Date: Mar. 15, 2012

(54) CAPACITIVE TOUCH SCREEN AND MANUFACTURING METHOD THEREOF

(75) Inventors: Woon Chun Kim, Gyunggi-do (KR); Yong Soo Oh, Gyunggi-do (KR); Jong Young Lee, Gyunggi-do (KR)

(73) Assignee: SAMSUNG ELECTRO-MECHANICS CO., LTD., Gyunggi-do (KR)

(21) Appl. No.: 13/021,085

(22) Filed: Feb. 4, 2011

(30) Foreign Application Priority Data
Sep. 13, 2010 (KR) 1020100089433

(51) Int. Cl. G06F 3/045; H05K 3/00

(52) U.S. Cl. 345/174; 29/829

(57) ABSTRACT

Disclosed herein are a capacitive touch screen and a manufacturing method thereof. The capacitive touch screen includes a base member on which a plurality of electrode patterns are formed; a conductive adhesive member formed on ends of the electrode patterns; and a window disposed on an upper side of the base member and having a plurality of electrode wirings formed in the outer side thereof to be conducted with the electrode patterns by the conductive adhesive member and to be opposite to the electrode patterns.

### CROSS REFERENCE TO RELATED APPLICATION

This application claims the benefit of Korean Patent Application No. 10-2010-0089433, filed on Sept. 13, 2010, entitled “Capacitive Touch Screen And Manufacturing Method Thereof”, which is hereby incorporated by reference in its entirety into this application.

### BACKGROUND OF THE INVENTION

1. Technical Field

The present invention relates to a capacitive touch screen and a manufacturing method thereof.

2. Description of the Prior Art

With the development of a mobile communication technology, user terminals such as cellular phones, PDAs, and navigations can serve as a display unit that simply displays character information as well as a unit for providing various and complex multi-media such as audio, moving picture, radio internet web browser, etc. Due to a recent demand for a larger display screen within a terminal having a limited size, a display scheme adopting a touch screen has been more in the limelight. The touch screen integrates a screen and coordinate input units, thereby making it possible to save a space as compared to a key input scheme according to the prior art.

A type of current mainly used touch screen is largely classified into two schemes.

First, a resistive touch screen has a shape in which an upper substrate formed with an upper resistive film and a lower substrate formed with a lower resistive film are spaced from each other by a spacer and are disposed to contact each other by external pressure. When an upper substrate formed with an upper electrode film is pressed by an input unit such as fingers, pens or the like, the upper/lower electrode films are conducted and a change in voltage according to a change in resistance value of the positions is recognized by a controller, such that the touched coordinates are recognized.

A capacitive touch screen has a structure in which an upper substrate formed with a first electrode pattern having a first directionality and a lower substrate formed with a second electrode pattern having a second directionality are spaced from each other and an insulator is inserted therebetween in order to prevent the first electrode pattern from contacting the second electrode pattern. In addition, the upper substrate and the lower substrate are formed with an electrode wirings connected to the electrode patterns. The electrode wirings transfer the change in capacitance generated in the first electrode pattern and the second electrode pattern according to the touch of the input unit with the touch screen to a controller.

A research into the capacitive touch screen has been progressed to increase the efficiency of multi-touch and the number of electrode patterns. As a result, the number of electrode wirings is also increased.

The capacitive touch screen according to the prior art separately configures the upper substrate and the lower substrate to form the electrode patterns and the electrode wirings, such that there is a problem in that the configuration of the touch screen becomes complicated. A separate insulator is required to isolate the electrode patterns formed on the upper substrate and the lower substrate from each other.

In addition, a portion of the capacitive touch screen according to the prior art is configured to have a single layer, not a two-layered structure. However, the single layer capacitive touch screen according to the prior art has a complicated structure since the electrode patterns and the electrode wirings are formed on the same plane, thereby causing the short problem between the electrode wirings.

Further, the single-layer capacitive touch screen according to the prior art causes several problems during the manufacturing process. Since the electrode patterns and the electrode wirings are formed on the same member, when the electrode wirings are formed after the electrode patterns are formed, the electrode patterns may be damaged or the electrode wirings may be damaged. In particular, when the electrode pattern is made of a conductive polymer and the etching process or the heat treatment process is performed during a process of forming an electrode wiring, there is a problem in that the sheet resistance of the electrode pattern is changed due to the modification of the conductive polymer.

### SUMMARY OF THE INVENTION

The present invention has been made in an effort to provide a capacitive touch screen capable of increasing a degree of freedom in terms of a design and preventing defects of electrode wirings and electrode patterns by disposing the electrode patterns and the electrode wirings on different planes.

Further, the present invention has been made in an effort to provide a method of manufacturing a capacitive touch screen capable of manufacturing a touch screen without causing defects of electrode patterns during the formation of electrode wirings by forming electrode patterns on a base member and the electrode wiring on a window and then conducting between the electrode patterns and the electrode wirings.

A capacitive touch screen according to a preferred embodiment of the present invention includes: a base member on which a plurality of electrode patterns are formed; a conductive adhesive member formed on ends of the electrode patterns; and a window disposed on an upper side of the base member and having a plurality of electrode wirings formed in the outer side region thereof to be conducted with the electrode patterns by the conductive adhesive member and to be opposite to the electrode patterns.

The capacitive touch screen may further include a covering film formed in the outer side region on the upper surface of the window to cover the electrode wirings.

The electrode pattern may be made of a conductive polymer.

The capacitive touch screen may further include a double-sided adhesive member formed in the outer side region on the upper surface of the base member to bond the window to the base member.

The end of the electrode pattern may be provided with steps and the conductive adhesive member may be formed on the steps.

The electrode pattern may be configured to include a first electrode pattern and a second electrode pattern formed to intersect with each other, the first electrode pattern may include a plurality of first sensing units and a first connection unit connecting the adjacent first sensing units, the second electrode pattern includes a plurality of second sensing parts formed on the same plane as the first sensing part and a second connection part connecting the adjacent second sensing parts, and the second connection unit may be formed on the upper side of the first connection unit to intersect with each other.

The capacitive touch screen may further include an insulating pattern disposed between the first connection unit and the second connection unit to prevent the first connection part and the second connection part from contacting each other.

A method of manufacturing a capacitive touch screen according to another preferred embodiment of the present invention includes: forming a plurality of electrode patterns on one surface of a base member and forming a conductive adhesive member on ends of the electrode patterns; forming a plurality of electrode wirings on one surface of a window; and bonding the base member to the window so that the electrode wirings and the electrode patterns are conducted with each other by bonding the electrode wirings to the conductive adhesive member.

The electrode wiring may be made of metal and is formed by a sputtering scheme.

The electrode pattern may be made of a conductive polymer.

The method of manufacturing a capacitive touch screen may further include forming a covering film covering the electrode wirings in the outer side region on the upper surface of the window.

The forming the conductive adhesive member may further include forming steps on the ends of the electrode patterns, wherein the conductive adhesive member may be formed on the steps.

The method of manufacturing a capacitive touch screen may further include prior to the bonding the base member to the window, forming a double-sided adhesive member bonding the base member to the window in the outer side region on the upper surface of the base member or the outer side region on the lower surface of the window.

### BRIEF DESCRIPTION OF THE DRAWINGS

FIG. 1 is a cross-sectional view schematically showing a capacitive touch screen according to the present invention;

FIG. 2 is a plan view showing a base member and a top surface and a rear surface of a window of a touch screen shown in FIG. 1;

FIG. 3 is a plan view showing a base member and a top surface and a rear surface of a window according to another preferred embodiment of the present invention;

FIGS. 4 and 5 are enlarged views showing in detail the electrode pattern shown in FIG. 3; and

FIGS. 6 to 8 are cross-sectional views schematically showing a modified example of the touch screen shown in FIG. 1; and

FIG. 9 is a flow chart schematically showing a manufacturing process of a capacitive touch screen according to the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of a linear vibrator according to the present invention will be described in detail with reference to the accompanying drawings.

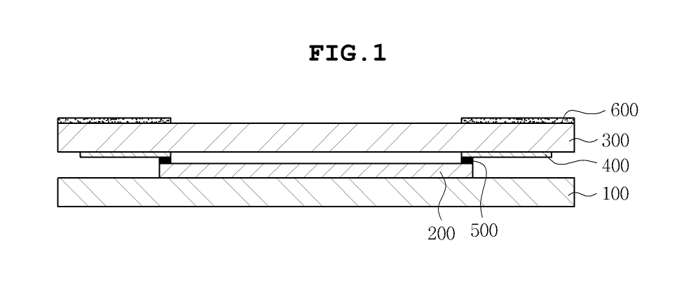

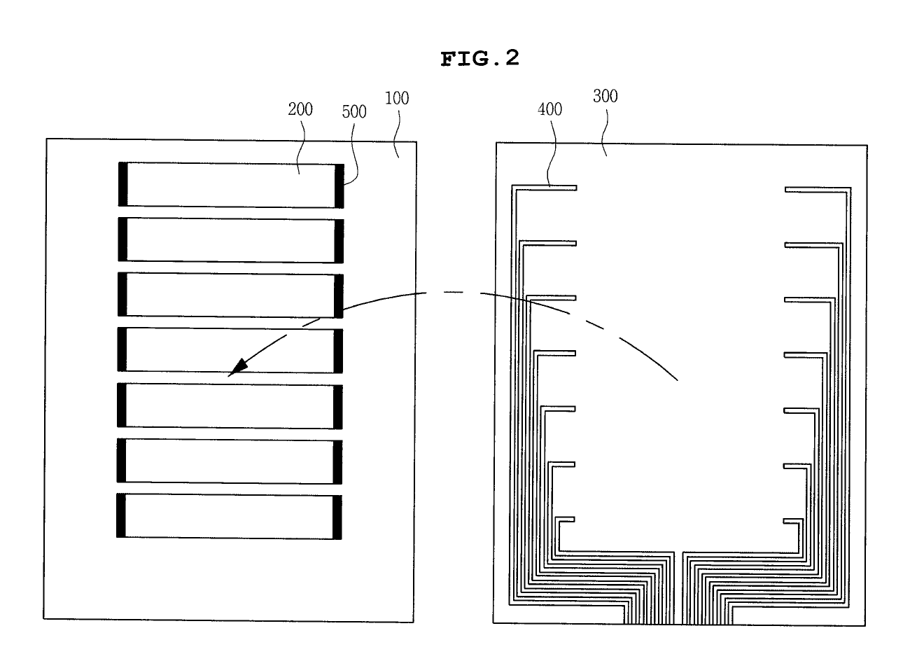

FIG. 1 is a cross-sectional view schematically showing a capacitive touch screen according to the present invention and FIG. 2 is a plan view showing a base member and a top surface and a rear surface of a window of a touch screen shown in FIG. 1. Hereinafter, a capacitive touch screen (hereinafter, referred to as a touch screen) according to the present embodiment will be described with reference to these figures.

In the touch screen according to the present invention, a plurality of electrode patterns 200 are formed on a base member 100, electrode wirings 400 connected to the electrode patterns 200 are formed on a window 300, and the electrode patterns 200 and the electrode wirings 400 are conducted to each other through a conductive adhesive member 500 formed on an end of the electrode pattern 200.

As the base member 100, a glass substrate, a film substrate, a fiber substrate, a paper substrate, and so on, which are a transparent member, may be used. Among them, the film substrate may be made of polyethyleneterephthalate (PET), polymethylmetacrylate (PMMA), polypropylene (PP), polyethylene (PE), polyethylenenaphthalate (PEN), polycarbonate (PC), polyethersulfone (PES), polyimide (PI), polyvinylalcohol (PVA), cyclic olefin copolymer (COC), styrene polymer, etc. but is not particularly limited thereto. The material of the base member 100 may be selected according to the kind or purpose of the terminal to which the touch screen is applied.

The electrode pattern 200 may use a conductive material such as indium tin oxide (ITO). The electrode pattern 200 may be made of a conductive material by known schemes, such as a gravure printing scheme, an inkjet printing scheme, a photolithography scheme.

In this case, the electrode pattern 200 may be made of a conductive polymer. The conductive polymer may include an organic compound, such as polythiophene, Polypyrrole, polyaniline, polyacetylene, polyphenylene, or the like. In particular, among the polythiophene, poly-3,4-ethylenedioxythiophene/polystyrenesulfonate (PEDOT/PSS) compound is most preferable and at least one of the organic compound may be mixed. The conductive polymer has advantages in saving a manufacturing cost simultaneously with having a sheet resistance equivalent to ITO.

The shape of the electrode pattern 200 may be practiced in various forms. As shown in FIG. 2, a bar-type electrode pattern 200 is generally used. In this case, the plurality of electrode patterns 200 are formed in parallel with the adjacent electrode patterns while having a bar shape in order to have uniform resistance. In this case, the plurality of electrode patterns may have the same area and shape.

The touch screen according to the present invention includes a window 300 disposed over the base member 100 and having the plurality of electrode wirings 400 formed at the outer side thereof to be opposite to the electrode patterns 200.

The window 300 covers the electrode pattern 200 and the glass substrate, the film substrate, the fiber substrate, and the paper substrate may be used to provide a surface contacting the input unit.

Since the inside region of the touch screen including the window 300 is an active region through which images pass, the electrode pattern 200 disposed in the inside region is made of a transparent conductive material, but since the outer side is an inactive region through which images do not pass, the electrode wiring 400 is not necessarily transparent. Therefore, the electrode wiring 400 may be made of a metal material having small resistance such as silver (Ag) paste but may be made of the same material as the electrode pattern 200.

The plurality of electrode wirings 400 formed on the lower surface of the window 300 to be opposite to the electrode pattern 200 may have one end connected to the electrode pattern 200 and the other ends collected at one side of the window 300. This is to facilitate the connection with the FPC when transferring the change in capacitance generated in the electrode pattern 200 to the controller.

In order to connect the electrode patterns 200 formed on the base member 100 to the electrode wirings 400 formed on the window 300, the end of the electrode pattern 200 is provided with a conductive adhesive member 500.

Meanwhile, in FIGS. 1 and 2, both ends of the electrode pattern 200 are provided with the conductive adhesive member 500 to connect the electrode wirings 400 to both ends of the electrode pattern 200, respectively, which is by way of example only. The electrode wirings 400 may be connected to only one end of the electrode pattern 200 according to a coordinate detection scheme of the touch screen. Although the electrode wirings 400 are connected to only one end of the electrode pattern 200, when a small amount of charges are applied to the electrode pattern 200 through the electrode wirings 400, the charge redistribution phenomenon occurs according to the external touch after a small amount of charges are supplied to an RC equivalent circuit including resistance component and capacitance. The change in voltage generated at that time is measured by the controller, thereby calculating the coordinates of the touched points. The coordinate detection scheme is known and therefore, the detailed description thereof will be omitted.

Further, in order to reinforce the adhesion between the electrode patterns 200 and the electrode wirings 400 by the conductive adhesive member 500, an optical adhesive layer (not shown) may be further formed between the electrode pattern 200 and the lower surface of the window 300.

A covering film 600 covering the electrode wirings 400 formed on the lower surface of the window 300 may be formed in the outer side on the upper surface of the window 300. When the electrode wirings 400 are made of metal such as silver paste, the electrode wirings 400 may be recognized from the outside. In order to prevent it, the covering film 600 is formed. The covering film 600 may be formed by printing ink having low brightness such as black ink in the outer side on the upper surface of the window 300.

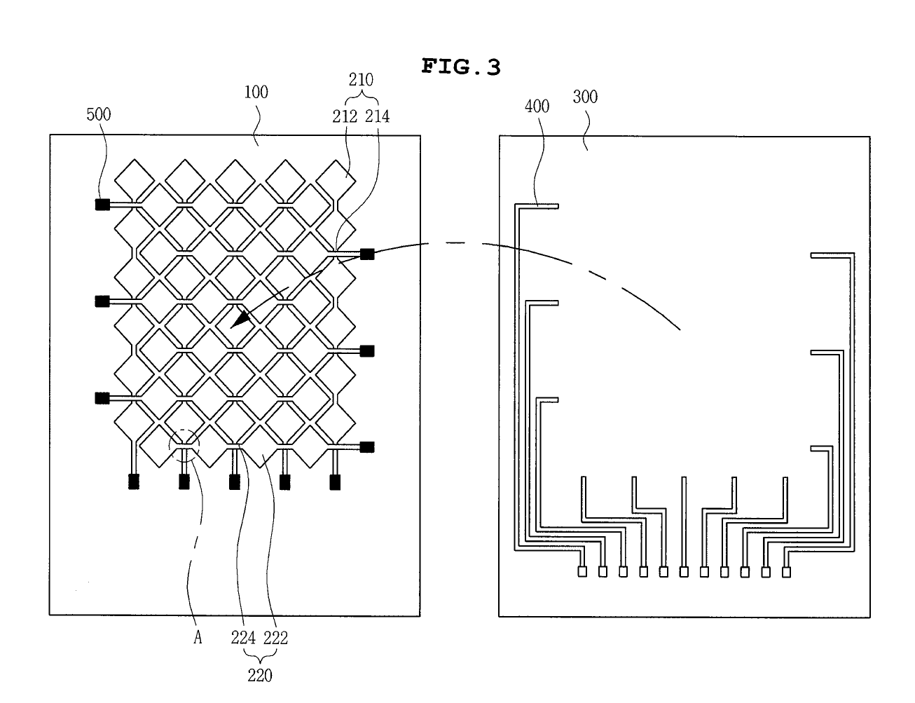

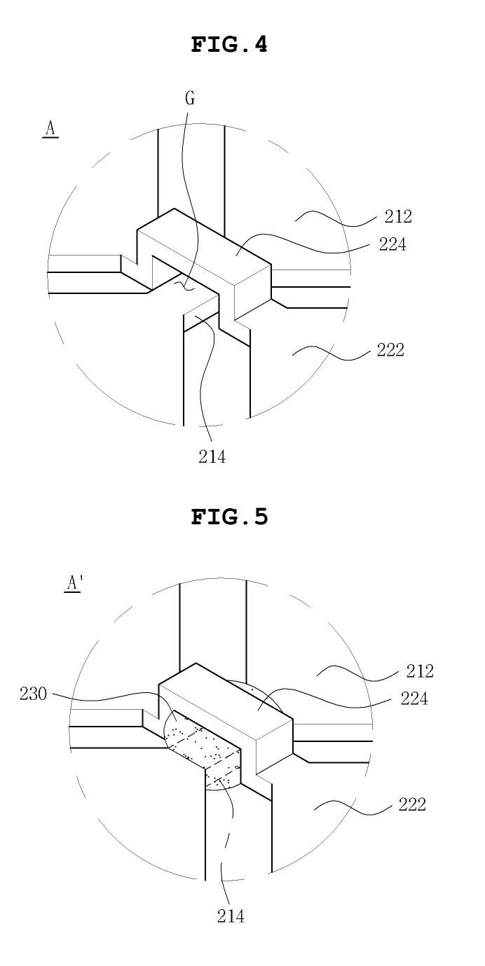

FIG. 3 is a plan view showing a base member and a top surface and a rear surface of a window according to another preferred embodiment of the present invention and FIGS. 4 and 5 are an enlarged view showing in detail the electrode pattern shown in FIG. 3. Hereinafter, the capacitive touch screen (hereinafter, touch screen) according to another preferred embodiment of the present invention will be described with reference to these figures. However, a detailed description of the same configuration as that described with reference to FIGS. 1 to 3 will be omitted.

In the touch screen according to the preferred embodiment, a first electrode pattern 210 and a second electrode pattern 220 having directionality intersecting with each other are formed on the base member 100. In the touch screen shown in FIG. 2, although the electrode patterns have the same directionality, the touch screen according to the preferred embodiment forms the electrode patterns 210 and 220 having different directionality on the base member 100, thereby making it possible to more accurately measure the coordinates of the touched points.

The first electrode pattern 210 has a shape where a first sensing part 212 and the first connection part 214 are repeated, wherein the plurality of electrode patterns are formed in parallel on the upper surface of the base member 100 in a first direction (Y direction). At this time, the first sensing part 212 measures the change in capacitance when a user's hand touches the touch screen and the first connection part 214 connects the plurality of first sensing parts 212.

Meanwhile, although the first sensing part 212 has a diamond shape in FIG. 3, this is provided by way of example only. Therefore, the first sensing part 122 may be formed in other polygonal shapes.

The second electrode pattern 220 is formed on the upper surface of the base member 100, like the above-mentioned first electrode pattern 210. In addition, the second electrode pattern 220 has a shape where a second sensing part 222 and a second connection part 224 are repeated, wherein the plurality of electrode patterns are formed in parallel in a second direction (X direction).

In this configuration, the second connection part 224 is formed to be intersected at the upper side of the first connection part 214 (bridge structure), such that the second electrode pattern 220 is electrically isolated from the first electrode pattern 210 without being connected to the first electrode pattern 210.

More specifically describing the bridge structure with reference to FIGS. 4 and 5, the second connection part 224 is formed on the first connection part 214 formed on the base member 100 to intersect with each other, having an air gap G formed therebetween or may form a bridge structure, having an insulating pattern 230 between the first connection part 214 and the second connection part 224 to prevent the first connection part and the second connection part from contacting each other. In this case, the insulating pattern 230 is made of a transparent resin material.

The bridge structure shown in FIG. 4 may minimize the generation of parasitic capacitance and the bridge structure shown in FIG. 5 increases the stability of the second connection part 224, thereby making it possible to prevent the short between the second connection part 224 and the first connection part 214.

Meanwhile, ends of the electrode patterns 210 and 220 shown in FIG. 3 are provided with the conductive adhesive member 500 connecting the electrode patterns 210 and 220 to the electrode wirings 400.

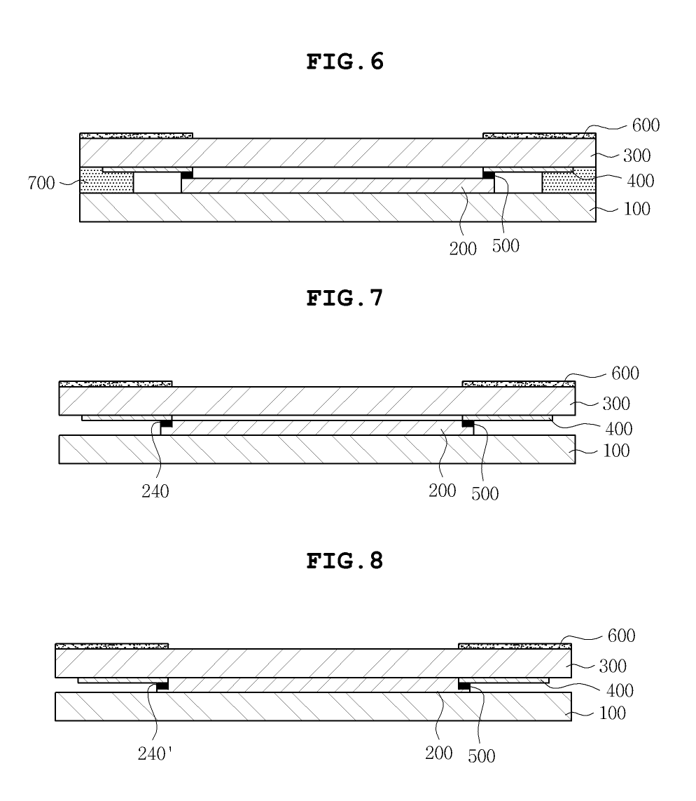

FIGS. 6 and 7 are a cross-sectional view schematically showing a modified example of the touch screen of FIG. 1. Hereinafter, another preferred embodiment of the present invention will be described with reference to these figures.

First, as shown in FIG. 6, the touch screen according to the preferred embodiment further includes a double-sided adhesive member 700 formed at the outer side region (or an outer side of the lower surface of the window 300) on the upper surface of the base member 100 to bond the window 300 to the base member 100.

The double-sided adhesive member 700 supports the window 300 disposed on the upper side thereof to firmly support the touch screen and prevents foreign materials generated from the outside from infiltrating into the touch screen.

As shown in FIGS. 7 and 8, in the touch screen according to another preferred embodiment, the end of the electrode pattern 200 is provided with steps 240 and 240′ and the conductive adhesive member 500 is provided with steps 240 and 240′.

In the touch screen shown in FIG. 1, the air gap between the window 300 and the electrode pattern 200 is generated due to the thickness of the conductive adhesive member 500 formed at the end of the electrode pattern 200. This is a factor of degrading the touch sensitivity due to the increase in distance between the window 300 and the electrode pattern 200 and the disposition of an air having a low dielectric constant.

In the touch screen according to the preferred embodiment, the end of the electrode pattern 200 is provided with the steps 240 and 240′ so that the conductive adhesive member 500 is not protruded from the electrode pattern 200, thereby making it possible to solve the above-mentioned problem.

However, the depth of the steps 240 and 240′ may be practiced while being modified in a smaller range than a sum of the heights of the conductive adhesive member 500 and the electrode wiring 400.

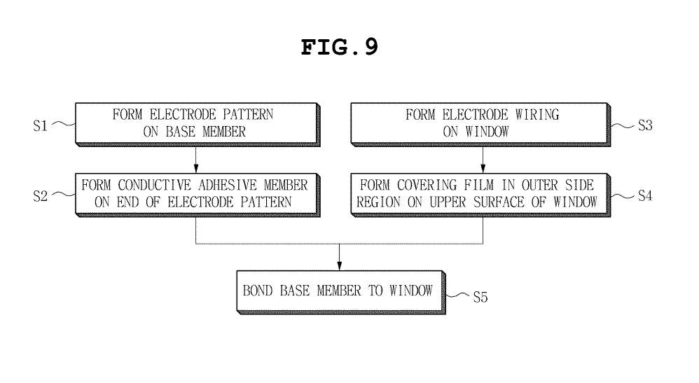

FIG. 9 is a flow chart showing a process of manufacturing a capacitive touch screen according to the present invention. A method of manufacturing a touch screen according to the present invention will be described with reference to FIG. 9.

The manufacturing method according to the present invention forms the electrode patterns on the base member and forms the electrode wirings on the window, respectively. The touch screen according to the prior art sequentially or simultaneously forms the electrode patterns and the electrode wirings on a single substrate, such that there is a problem in that the short between the electrode patterns and the electrode wirings occurs or the damage occurs in one of them first formed.

In particular, when the electrode pattern is made of the conductive polymer, there is a problem in that the conductive polymer weak against moisture and heat is modified during the formation of the electrode wirings. Therefore, when forming the electrode wirings, there is a problem in that the wet etching process or the annealing process is limited.

The manufacturing method according to the present invention forms the electrode patterns and the electrode wirings on different members, respectively, to solve the above-mentioned problem and forms the touch screen by conducting between the electrode patterns and the electrode wirings through the conductive adhesive member.

Describing in more detail, the plurality of electrode patterns are first formed on one surface of the base member (S1). Next, the ends of the electrode patterns are provided with the conductive adhesive member (S2). The one surface of the window is provided with the plurality of electrode wirings (S3). The above-mentioned three steps may be performed independently of sequence.

In addition, when the structure covering the electrode wirings is formed on the touch screen itself without using a bezel structure using a housing, the covering film may be formed by printing the ink having low brightness such as black ink in the outer side on the upper surface of the window (S4).

Thereafter, the electrode wiring bonds the base member to the window so that the electrode wirings and the electrode patterns are conducted with each other through the conductive adhesive member (S5).

Meanwhile, when forming the conductive adhesive member, the manufacturing method may further include forming the steps at the ends of the electrode patterns. The steps are formed by removing a portion of the electrode patterns by laser, or the like. When the steps are formed, the conductive adhesive member is disposed on the steps. It may be formed by spotting the conductive adhesive or attaching the conductive adhesive sheet.

In addition, prior to the bonding the base member to the window, the manufacturing method may further include forming a double-sided adhesive member bonding the base member to the window in the outer side on the upper surface of the base member or in the outer side on the lower surface of the window. As the double-sided adhesive member, a double-sided adhesive sheet may be used and may be disposed between the base member and the window during the bonding of the base member to the window, to firmly support the touch screen and prevent foreign materials generated from the outside from infiltrating into the touch screen.

The capacitive touch screen according to the present invention includes the electrode patterns and the electrode wirings disposed on different planes by forming the electrode patterns on the base member and electrode wirings on the window, thereby making it possible to prevent the short problem between the electrode patterns and the electrode wirings.

In addition, the method of manufacturing the capacitive touch screen according to the present invention forms the electrode wirings and the electrode patterns on the base member and the window, respectively, and bonds them, thereby making it possible to prevent defects generated in the electrode pattern or the electrode wirings generated during the formation of the electrode wiring or the electrode patterns. In particular, when the electrode pattern is made of a conductive polymer, the modification of the electrode pattern can be prevented even though the etching process or the heat treatment process is performed during the formation of the electrode wirings.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A capacitive touch screen, comprising:
a base member on which a plurality of electrode patterns are formed;
a conductive adhesive member formed on ends of the electrode patterns; and
a window disposed on an upper side of the base member and having a plurality of electrode wirings formed in the outer side thereof to be conducted with the electrode patterns by the conductive adhesive member and to be opposite to the electrode patterns.

2. The capacitive touch screen as set forth in claim 1, further comprising a covering film formed in the outer side on the upper surface of the window to cover the electrode wirings.

3. The capacitive touch screen as set forth in claim 1, wherein the electrode pattern is made of a conductive polymer.

4. The capacitive touch screen as set forth in claim 1, wherein the electrode pattern is configured to include a first electrode pattern and a second electrode pattern formed to intersect with each other;
the first electrode pattern includes a plurality of first sensing parts and a first connection part connecting the adjacent first sensing parts;
the second electrode pattern includes a plurality of second sensing parts formed on the same plane as the first sensing part and a second connection part connecting the adjacent second sensing parts, and
the second connection part is formed on the upper side of the first connection part to intersect with each other.

5. The capacitive touch screen as set forth in claim 4, further comprising an insulating pattern disposed between the first connection part and the second connection part to prevent the first connection part and the second connection part from contacting each other.

6. The capacitive touch screen as set forth in claim 1, further comprising a double-sided adhesive member formed in the outer side on the upper surface of the base member to bond the window to the base member.

7. The capacitive touch screen as set forth in claim 1, wherein the end of the electrode pattern is provided with steps and the conductive adhesive member is formed on the steps.

8. A method of manufacturing a capacitive touch screen, comprising:
forming a plurality of electrode patterns on one surface of a base member and forming a conductive adhesive member on ends of the electrode patterns;
forming a plurality of electrode wirings on one surface of a window; and
bonding the base member to the window so that the electrode wirings and the electrode patterns are conducted with each other by bonding the electrode wirings to the conductive adhesive member.

9. The method of manufacturing a capacitive touch screen as set forth in claim 8, wherein the electrode wiring is made of metal and is formed by a sputtering scheme.

10. The method of manufacturing a capacitive touch screen as set forth in claim 8, wherein the electrode patterns are made of a conductive polymer.

11. The method of manufacturing a capacitive touch screen as set forth in claim 8, further comprising forming a covering film covering the electrode wirings in the outer side on the upper surface of the window.

12. The method of manufacturing a capacitive touch screen as set forth in claim 8, wherein the forming the conductive adhesive member further includes forming steps on the ends of the electrode patterns, the conductive adhesive member being formed on the steps.

13. The method of manufacturing a capacitive touch screen as set forth in claim 8, further comprising prior to the bonding the base member to the window, forming a double-sided adhesive member bonding the base member to the window in the outer side on the upper surface of the base member or the outer side on the lower surface of the window.
